(19) United States
(12) Patent Application Publication
(10) Pub. No.: US 2025/0024720 A1
(43) Pub. Date: Jan. 16, 2025

(54) DISPLAY DEVICE AND METHOD OF PROVIDING THE SAME

(71) Applicant: Samsung Display Co., Ltd., Yongin-si (KR)

(72) Inventors: INSEOK LIM, Yongin-si (KR); SANGWOOK LEE, Yongin-si (KR); YEOUNGKEOL WOO, Yongin-si (KR); YUNG BIN CHUNG, Yongin-si (KR)

(21) Appl. No.: 18/676,609

(22) Filed: May 29, 2024

(30) Foreign Application Priority Data
Jul. 11, 2023 (KR) 10-2023-0090021

(51) Int. Cl. H10K 59/131; H10K 59/12

(52) U.S. Cl. CPC H10K 59/131; H10K 59/1201

(57) ABSTRACT

A display device includes a circuit layer and a light emitting element which is on the circuit layer and connected thereto. The circuit layer includes a transistor, an insulation layer on the transistor ad including a side surface which defines a contact-hole of the insulation layer at which a portion of the transistor is exposed to outside the insulation layer, and an upper surface from which the side surface extends, and a bridge electrode which extends along the side surface of the insulation layer and contacts the portion of the transistor which is exposed to outside the insulation layer. And a connection electrode which connects the light emitting element to the transistor. The connection electrode includes a first connection electrode which is directly on the bridge electrode and spaced apart from the portion of the transistor which is exposed to outside the insulation layer.

This U.S. non-provisional patent application claims priority to Korean Patent Application No. 10-2023-0090021, filed on Jul. 11, 2023, and all the benefits accruing therefrom under 35 U.S.C. § 119, the entire contents of which are hereby incorporated by reference.

### BACKGROUND

### (1) Field

The present disclosure herein relates to a display device and a method of providing the same. More particularly, the present disclosure relates to a display device having high-resolution, high-speed driving properties.

### (2) Description of the Related Art

A display device includes a plurality of pixels, and a driving circuit (for example, a scan driving circuit and a data driving circuit) for controlling the plurality of pixels. Each of the plurality of pixels includes a display element and a driving circuit of the pixel for controlling the display element. The driving circuit of the pixel may include a plurality of transistors which are organically connected to each other.

### SUMMARY

As the size and resolution of a display device having pixels gradually increase, the number of signal lines and connection electrodes which connect the display elements with the transistors included in the pixels increases. As a result, the degree of integration of the driving circuits included in the pixels increases.

The present disclosure provides a display device with improved reliability, and a method for manufacturing (or providing) the same.

An embodiment of the invention provides a display device including a circuit layer, and a light emitting element on the circuit layer and connected thereto, where the circuit layer comprises a transistor, an insulation layer on the transistor comprising a side surface which defines a contact-hole of the insulation layer at which a portion of the transistor is exposed to outside the insulation layer, and an upper surface from which the side surface extends, a bridge electrode which extends along the side surface of the insulation layer and contacts the portion of the transistor which is exposed to outside the insulation layer; and a connection electrode which connects to the transistor, the connection electrode comprising a first connection electrode which is directly on the bridge electrode and spaced apart from the portion of the transistor which is exposed to outside the insulation layer.

In an embodiment, the transistor may include a semiconductor layer which defines the portion of the transistor which is exposed to outside the insulation layer.

In an embodiment, the semiconductor layer includes an upper surface at which the semiconductor layer is exposed to outside the insulation layer, and the transistor may further include a second connection electrode on the upper surface of the semiconductor layer.

In an embodiment, the second connection electrode may be spaced apart from the first connection electrode on the bridge electrode, and the second connection electrode may be electrically connected to the first connection electrode via the bridge electrode.

In an embodiment, a width of the contact-hole may be about 0.5 micrometer to about 2 micrometers.

In an embodiment, a depth of the contact-hole is recessed may be about 1 micrometer to about 1.5 micrometer.

In an embodiment, the bridge electrode may include a material different from each of a material of the first connection electrode and of the second connection electrode.

In an embodiment, the bridge electrode may have a length along the side surface of the insulation layer, and the length of the bridge electrode may be smaller than a depth of the contact-hole.

In an embodiment, the bridge electrode has an upper surface which is closest to the upper surface of the insulation layer, and a portion of the side surface which is between the upper surface of the insulation layer and the upper surface of the bridge electrode is exposed to outside the bridge electrode. The first connection electrode may directly contact an upper surface of the bridge electrode and the portion of the side surface which is exposed to outside the bridge electrode.

In an embodiment, the insulation layer may further include a first insulation layer on the transistor, and a second insulation layer on the first insulation layer, where the contact-hole may pass through the first insulation layer and the second insulation layer.

In an embodiment, the contact-hole may include a first hole portion defined by a side surface of the first insulation layer, and a second hole portion defined by a side surface of the second insulation layer, where a size of the first hole portion may be smaller than a size of the second hole portion.

In an embodiment, the first connection electrode comprises portions which extend from the upper surface of the insulation layer and along the side surface thereof, the portions being spaced apart from each other to define an upper hole may be in the first connection electrode, where a size of the upper hole may increase in a direction from the upper surface of the insulation layer to the portion of the transistor which is exposed to outside the insulation layer.

In an embodiment, the bridge electrode may include an n-type dopant.

In an embodiment, the circuit layer may further include an organic layer which is on the insulation layer and comprises a side surface defining an upper contact-hole of the organic layer at which a portion of the first connection electrode is exposed to outside the organic layer.

In an embodiment, the circuit layer may further include an upper bridge electrode extended along a side surface of the organic layer defining the upper contact-hole, and contacting the portion of the first connection electrode which is exposed to outside the organic layer, and an upper connection electrode which electrically connects the light emitting element to the connection electrode, the upper connection electrode being directly on the upper bridge electrode and spaced apart from the portion of the first connection electrode which is exposed to outside the organic layer.

In an embodiment of the invention, a method for manufacturing (or providing) a display device includes providing a semiconductor pattern of a transistor, and an insulation layer on the transistor, forming (or providing) a contact-hole in the insulation layer, which exposes a portion of the semiconductor pattern to outside, in the insulation layer having a side surface which defines the contact-hole and an upper surface extended from the side surface, providing a bridge electrode along the side surface of the insulation layer to contact the portion of the semiconductor pattern which is exposed to outside the insulation layer, and providing a first connection electrode which connects a light emitting element to the transistor, the first connection electrode extended along the bridge electrode. In an embodiment, the first connection electrode may be electrically connected to the portion of the semiconductor pattern via the bridge electrode.

The method for manufacturing a display device according to an embodiment of the invention may further include providing a second connection electrode contacting the portion of the semiconductor pattern, and spaced apart from the first connection electrode along the bridge electrode.

In an embodiment, the providing of the first connection electrode and the providing of the second connection electrode may be respective portions of a same material layer.

In an embodiment, the providing of the bridge electrode may include providing a preliminary bridge electrode on the upper surface of the insulation layer, along the side surface of the insulation layer, and along the portion of the semiconductor pattern, and etching portions of the preliminary bridge electrode which are on the upper surface of the insulation layer and on the portion of the semiconductor pattern.

In an embodiment, the providing of the preliminary bridge electrode may be provided by is provided by chemical vapor deposition.

### BRIEF DESCRIPTION OF THE FIGURES

The accompanying drawings are included to provide a further understanding of the invention, and are incorporated in and constitute a part of this specification. The drawings illustrate embodiments of the invention and, together with the description, serve to explain principles of the invention. In the drawings:

FIG. 1 is a perspective view showing a display device according to an embodiment of the invention;

FIG. 2 is an exploded perspective view showing a display device according to an embodiment of the invention;

FIG. 3 is a cross-sectional view of a display panel according to an embodiment of the invention;

FIG. 4 is a top plan view of a display panel according to an embodiment of the invention;

FIG. 5 is a view illustrating an equivalent circuit of a pixel according to an embodiment of the invention;

FIG. 6 is a cross-sectional view of a display panel according to an embodiment of the invention;

FIG. 7 is an enlarged view of region AA′ of FIG. 6;

FIG. 8A is an enlarged view of a portion of a display device according to an embodiment of the invention;

FIG. 8B is an enlarged view of a portion of a display device according to an embodiment of the invention;

FIG. 8C is an enlarged view of a portion of a display device according to an embodiment of the invention;

FIG. 8D is an enlarged view of region BB′ of FIG. 6;

FIG. 9A is a cross-sectional view of a display panel according to an embodiment of the invention;

FIG. 9B is an enlarged view of region CC′ of FIG. 9A; and

FIG. 10A to FIG. 10E are cross-sectional views showing sequential processes in a method for manufacturing (or providing) a display device according to an embodiment of the invention.

### DETAILED DESCRIPTION

The invention may be modified in many alternate forms, and thus specific embodiments will be exemplified in the drawings and described in detail. It should be understood, however, that it is not intended to limit the invention to the particular forms disclosed, but rather, is intended to cover all modifications, equivalents, and alternatives falling within the spirit and scope of the invention.

In the present specification, when an element (or a region, a layer, a portion, etc.) is referred to as being related to another element such as being “on,” “connected to,” or “coupled to” another element, it means that the element may be directly disposed on/connected to/coupled to the other element, or that a third element may be disposed therebetween. In the present specification, when an element (or a region, a layer, a portion, etc.) is referred to as being related to another element such as being “directly disposed” on another element, it means that a third element is not disposed between the element and the another element. That is, when an element is “directly disposed” on another element, it means that the element and the another element are in “contact” with each other. As being in contact, elements may form an interface therebetween.

Like reference numerals refer to like elements. Also, in the drawings, the thickness, the ratio, and the dimensions of elements are exaggerated for an effective description of technical contents.

It will be understood that, although the terms “first,” “second,” etc. may be used herein to describe various elements, these elements should not be limited by these terms. These terms are only used to distinguish one element from another. For example, a first element may be referred to as a second element, and a second element may also be referred to as a first element in a similar manner without departing the scope of rights of the invention.

The terms of a singular form may include plural forms unless the context clearly indicates otherwise. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. Within the Figures and the text of the disclosure, a reference number indicating a singular form of an element may also be used to reference a plurality of the singular element.

In addition, terms such as “below,” “lower,” “above,” “upper,” and the like are used to describe the relationship of components shown in the drawings. The terms are used as a relative concept and are described with reference to the direction indicated in the drawings.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which the invention pertains. It is also to be understood that terms defined in commonly used dictionaries should be interpreted as having meanings consistent with the meanings in the context of the related art, and are expressly defined herein unless they are interpreted in an ideal or overly formal sense.

It should be understood that the term “comprise,” or “have” is intended to specify the presence of stated features, integers, steps, operations, elements, components, or combinations thereof in the disclosure, but do not preclude the presence or addition of one or more other features, integers, steps, operations, elements, components, or combinations thereof.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention will be described with reference to the accompanying drawings.

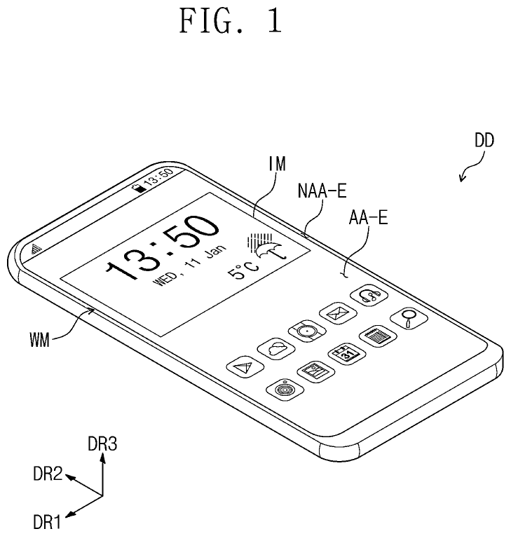

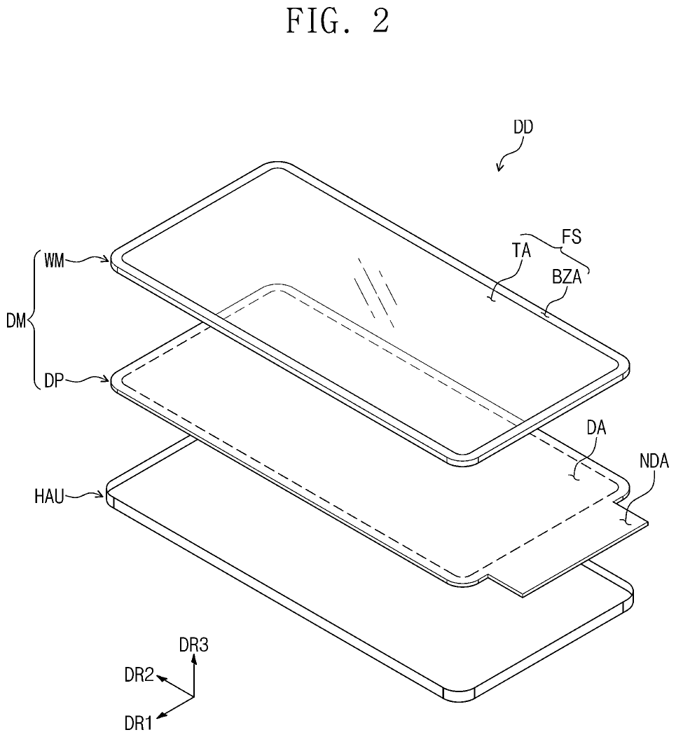

FIG. 1 is a perspective view showing a display device DD according to an embodiment of the invention. FIG. 2 is an exploded perspective view showing a display device DD according to an embodiment of the invention.

A display device DD may display an image IM via an active region AA-E. The active region AA-E may include or be disposed in a plane parallel to a plane defined by a first direction DR1 and a second direction DR2 crossing each other. A peripheral region NAA-E is adjacent to the active region AA-E. The peripheral region NAA-E may surround the active region AA-E in a plan view. However, the peripheral region NAA-E may be disposed adjacent to only one side of the active region AA-E, or may be omitted.

The display device DD according to the present embodiment may include a housing HAU and a display module DM. The display module DM according to the present embodiment may include a display panel DP and a window member WM.

The window member WM may cover the entire outer side of the display module DM. The window member WM may include a transmission region TA and a bezel region BZA. The front surface FS of the window member WM including the transmission region TA and the bezel region BZA may correspond to or define the front surface FS of the display device DD. The transmission region TA may correspond to the active region AA-E of the display device DD illustrated in FIG. 1, and the bezel region BZA may correspond to the peripheral region NAA-E of the display device DD illustrated in FIG. 1.

The transmission region TA may be an optically transparent region. The bezel region BZA may be a region having relatively low light transmittance compared to the transmission region TA. The bezel region BZA may have a predetermined color. The bezel region BZA is adjacent to the transmission region TA, and may surround the transmission region TA in the plan view. However, the bezel region BZA may be disposed adjacent to only one side of the transmission region TA, or a portion of the bezel region BZA may be omitted.

The display panel DP may include a display region DA and a non-display region NDA which is adjacent to the display region DA, such as being extended around the display region DA. The display region DA may be a region activated in response to an electrical signal. In the present embodiment, the display region DA may be a region in which the image IM (see FIG. 1) is displayed. The display region DA of the display panel DP may correspond to the active region AA-E of the display device DD illustrated in FIG. 1, and the non-display region NDA of the display panel DP may correspond to the peripheral region NAA-E of the display device DD illustrated in FIG. 1. The transmission region TA may overlap at least a portion of display region DA. The non-display region NDA may be a region covered by the bezel region BZA.

Although not illustrated in FIG. 1 and FIG. 2, an input sensing unit as an input sensing layer may be provided on the display panel DP, such as to face the display panel DP. The input sensing unit may sense an external input applied from the outside of the display module DM (or outside the display device DD). The external input may include various forms of external inputs, such as light, heat, pressure, or the like. The external input may be provided from an input tool such as a pen, a body part of a user, etc. The input sensing unit may be directly disposed on the display panel DP, or may be coupled to the display panel DP via a separate adhesive member.

The housing HAU may accommodate the display panel DP and the like. The housing HAU may be coupled to the window member WM.

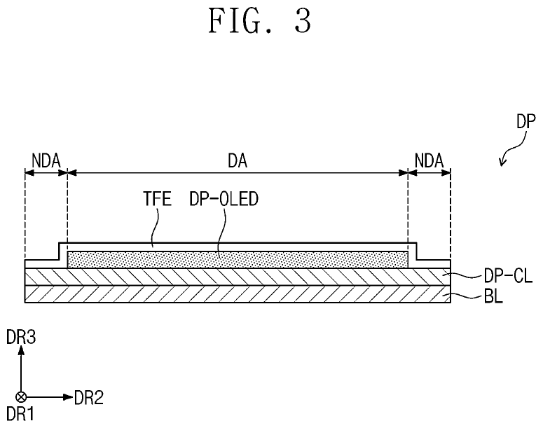

FIG. 3 is a cross-sectional view of a display panel DP according to an embodiment of the invention. Illustratively, FIG. 3 illustrates a cross-section of the display panel DP viewed from (or along) the first direction DR1. In an embodiment, the cross-section of FIG. 3 may also be defined viewed along the second direction DR2.

Referring to FIG. 3, the display panel DP may include a base layer BL, a circuit layer DP-CL disposed on the base layer BL, a display element layer DP-OLED disposed on the circuit layer DP-CL, and an encapsulation layer TFE disposed on the display element layer DP-OLED. The display panel DP may include the display region DA and the non-display region NDA which is around the display region DA, without being limited thereto.

The base layer BL may include a flexible plastic material such as polyimide (PI). The display element layer DP-OLED may be disposed on the display region DA.

A plurality of pixels PX may be disposed in the circuit layer DP-CL and the display element layer DP-OLED. Each of the pixels PX may include transistors disposed in the circuit layer DP-CL and a light emitting element OLED disposed in the display element layer DP-OLED which is connected to one or more of the transistors, The configuration of a pixel PX will be described in detail below.

The encapsulation layer TFE may be disposed on the circuit layer DP-CL to cover the display element layer DP-OLED. The encapsulation layer TFE may protect the pixels PX from moisture, oxygen, and external foreign substances.

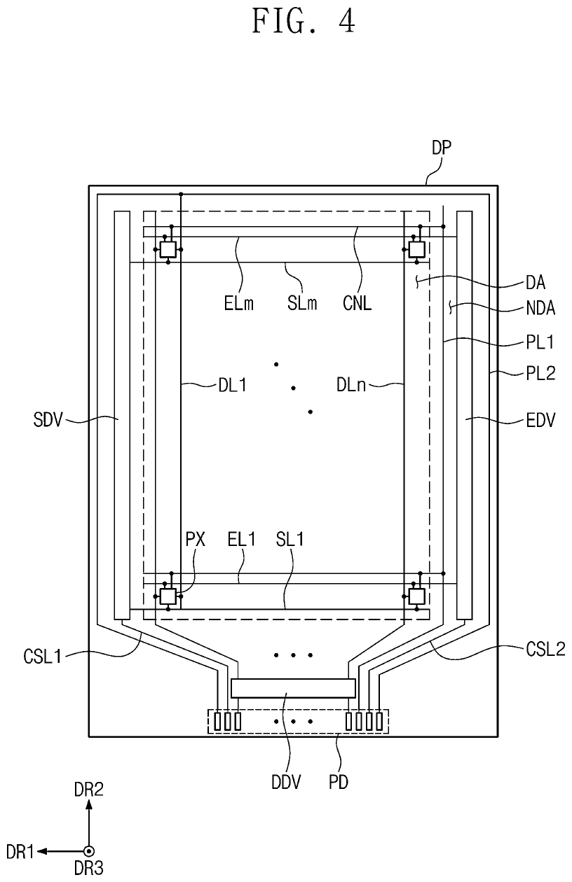

FIG. 4 is a plan view of a display panel DP according to an embodiment of the invention.

Referring to FIG. 4, the display panel DP may include a scan driver SDV, a data driver DDV, a light emission driver EDV, and a plurality of pads PD in a pad area. The display panel DP may have a rectangular shape which has short sides extending in the first direction DR1 and long sides extending in the second direction DR2, but the planar shape of the display panel DP is not limited thereto. The display panel DP may include the display region DA and the non-display region NDA which surrounds the display region DA, without being limited thereto.

The display panel DP may include a plurality of pixels PX, a plurality of scan lines SL1 to SLm, a plurality of data lines DL1 to DLn, a plurality of light emission lines EL1 to ELm, first and second control lines CSL1 and CSL2, first and second power lines PL1 and PL2, and connection lines CNL. As used herein, ‘m’ and ‘n’ are natural numbers.

The pixels PX may be disposed in the display region DA. The scan driver SDV and the light emission driver EDV may be disposed in the non-display region NDA which is adjacent to each of the long sides of the display panel DP. The data driver DDV may be disposed in the non-display region NDA which is adjacent to any one short side of the short sides of the display panel DP. When viewed on a plane, the data driver DDV may be adjacent to a lower end of the display panel DP which is closest to the pad area.

The scan lines SL1 to SLm may be extended in the first direction DR1 to be connected to the pixels PX and the scan driver SDV. The data lines DL1 to DLn may be extended in the second direction DR2 to be connected to the pixels PX and the data driver DDV. The light emission lines EL1 to ELm may be extended in the first direction DR1 to be connected to the pixels PX and the light emission driver EDV.

The first power line PL1 may be extended in the second direction DR2 and disposed in the non-display region NDA. The first power line PL1 may be disposed between the display region DA and the light emission driver EDV.

The connection lines CNL may be extended in the first direction DR1 and arranged in the second direction DR2 to be connected to the first power line PL1 and the pixels PX. A first voltage may be applied to the pixels PX via the first power line PL1 and the connection lines CNL connected to each other. The connection lines CNL may be substantially defined as a portion of the first power line PL1 which receives the first voltage.

The second power line PL2 is disposed in the non-display region NDA, and may extend along the long sides of the display panel DP and another short side of the display panel DP at which the data driver DDV is not disposed. The second power line PL2 may be disposed at an outer periphery than the scan driver SDV and the light emission driver EDV.

Although not illustrated, the second power line PL2 may be extended toward the display region DA to be connected to the pixels PX. A second voltage having a lower level than the first voltage may be applied to the pixels PX via the second power line PL2.

A first control line CSL1 is connected to the scan driver SDV, and may be extended toward a lower end of the display panel DP. A second control line CSL2 is connected to the light emission driver EDV, and may be extended toward the lower end of the display panel DP. The data driver DDV may be disposed between the first control line CSL1 and the second control line CSL2.

The pads PD are disposed in the non-display region NDA adjacent to the lower end of the display panel DP, and may be closer to the lower edge of the display panel DP than the data driver DDV. The data driver DDV, the first and second power lines PL1 and PL2, the first and second control lines CSL1 and CSL2 may be connected to the pads PD. The data lines DL1 to DLn are connected to the data driver DDV, and the data driver DDV may be connected to pads PD corresponding to the data lines DL1 to DLn.

Although not illustrated, the display device DD may further include a timing controller for controlling the operation of the scan driver SDV, the data driver DDV, and the light emission driver EDV and a voltage generation unit for generating the first and second voltages. The timing controller and the voltage generator may be connected to the display panel DP at corresponding pads PD thereof, via an external component such as a printed circuit board.

The scan driver SDV generates a plurality of scan signals as electrical signals, and the scan signals may be applied to the pixels PX via the scan lines SL1 to SLm. The data driver DDV generates a plurality of data voltages as electrical signals, and the data voltages may be applied to the pixels PX via the data lines DL1 to DLn. The light emission driver EDV generates a plurality of light emission signals as electrical signals, and the light emission signals may be applied to the pixels PX via the light emission lines EL1 to ELm.

The pixels PX may be provided with the data voltages in response to the scan signals. The pixels PX may display an image IM by emitting light of luminance corresponding to the data voltages in response to the light emission signals.

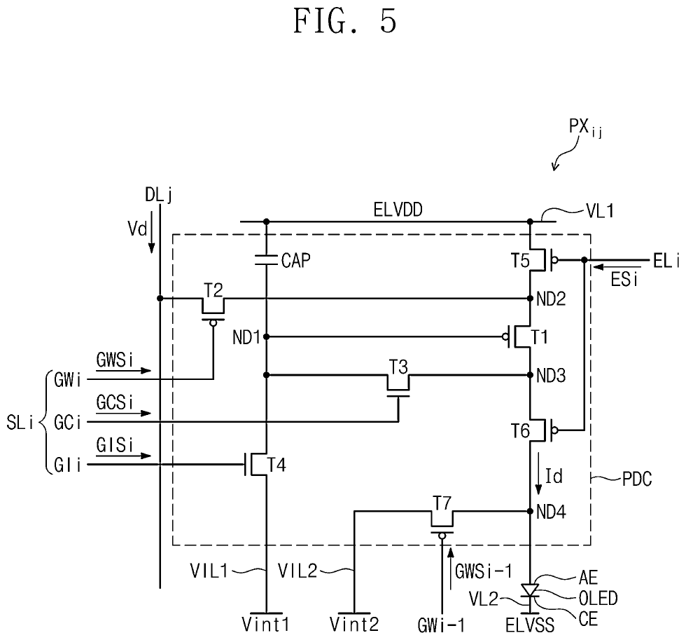

FIG. 5 is a view illustrating an equivalent circuit of a pixel PX according to an embodiment of the invention. In FIG. 5, a pixel PXij connected to an i-th scan line SLi, an i-th light emission line ELi, and a j-th data line DLj is exemplarily illustrated. Here, ‘i’ and ‘j’ represent natural numbers.

Referring to FIG. 5, the pixel PXij may include a light emitting element OLED, and a pixel driving circuit PDC which is electrically connected the light emitting element OLED. The pixel driving circuit PDC may include transistors T1 to T7 and a capacitor CAP. The transistors T1 to T7 and the capacitor CAP may control the amount of electrical current flowing in the light emitting element OLED, and the light emitting element OLED may generate light having a predetermined luminance according to the amount of electrical current provided thereto.

The i-th scan line SLi may include i-th first to third scan lines GWi, GCi, and GIi. The first scan line GWi receiving an i-th write scan signal GWSi may be defined as an i-th write scan line GWi. The second scan line GCi receiving an i-th compensation scan signal GCSi may be defined as a compensation scan line GCi. The third scan line GIi receiving an i-th initialization scan signal GISi may be defined as an initialization scan line GIi.

The transistors T1 to T7 may include first to seventh transistors T1 to T7. The first to seventh transistors T1 to T7 may each include a source electrode, a drain electrode, and a gate electrode. Hereinafter, the source electrode may be referred to as a source, the drain electrode may be referred to as a drain, and the gate electrode may be referred to as a gate.

In the present disclosure, “being electrically connected (or connected) between a transistor and a signal line, or between a transistor and a transistor” means that “an electrode of the transistor may have a shape of a single body with the signal line to define a portion thereof, or may be connected thereto via a third element like a connection electrode.”

The first to seventh transistors T1 to T7 may each be a transistor having an oxide semiconductor layer as a semiconductor layer, or a transistor having a low-temperature polycrystalline silicon (LTPS) semiconductor layer as the semiconductor layer. The first to seventh transistors T1 to T7 may each be an N-type transistor or a P-type transistor. For example, the first, second, fifth, sixth, and seventh transistors T1, T2, T5, T6, and T7 may each be a PMOS transistor having a LTPS semiconductor layer, and the third and fourth transistors T3 and T4 may each be an NMOS transistor having an oxide semiconductor layer. However, embodiments of the transistors T1 to T7 are not limited thereto. In addition, although the pixel driving circuit PDC including the seven transistors T1 to T7 is exemplarily illustrated, the number of transistors included in the pixel driving circuit PDC is not limited thereto.

The light emitting element OLED may be defined as an organic light emitting element. The light emitting element OLED may include a first electrode AE and a second electrode CE. For example, the first electrode AE may be an anode and the second electrode CE may be a cathode. The first electrode AE of the light emitting element OLED may be electrically connected to a first voltage line VL1 receiving a first driving voltage ELVDD. The second electrode CE of the light emitting element OLED may be electrically connected to a second voltage line VL2 receiving a second driving voltage ELVSS. The first voltage line VL1 may correspond to the first power line PL1 illustrated in FIG. 4, and the second voltage line VL2 may correspond to the second power line PL2 illustrated in FIG. 4.

The first transistor T1 may be electrically connected between the first voltage line VL1 receiving the first driving voltage ELVDD and the light emitting element OLED. The first transistor T1 may include a source connected to a second node ND2, a drain connected to a third node ND3, and a gate connected to a first node ND1. The first transistor T1 may be turned on by a voltage of the first node ND1. The first transistor T1 may receive a data voltage Vd transmitted by the data line DLj according to a switching operation of the second transistor T2 and supply a driving current Id to the light emitting element OLED. In the present embodiment, the first transistor T1 may be defined as a driving transistor.

The second transistor T2 may be electrically connected between the data line DLj and the first transistor T1. The second transistor T2 may include a source connected to the data line DLj, a drain connected to the second node ND2, and a gate connected to the first scan line GWi. The second transistor T2 and the first transistor T1 may be connected via the second node ND2. The second transistor T2 may be turned on by the write scan signal GWSi applied via the first scan line GWi. The second transistor T2 turned on by the write scan signal GWSi may transmit the data voltage Vd applied to the data line DLj to the source of the first transistor T1. In the present embodiment, the second transistor T2 may be defined as a switching transistor.

The third transistor T3 may be connected between the fourth transistor T4 and the first transistor T1. The third transistor T3 may include a source connected to the first node ND1, a drain connected to the third node ND3, and a gate connected to the second scan line GCi. The third transistor T3 and the first transistor T1 may be connected via the third node ND3. The third transistor T3 may be turned on by the compensation scan signal GCSi applied via the second scan line GCi. The third transistor T3 turned on by the compensation scan signal GCSi may electrically connect the gate of the first transistor T1 and the drain of the first transistor T1 to each other, and may diode-connect the first transistor T1. In the present embodiment, the third transistor T3 may be defined as a compensation transistor.

The fourth transistor T4 may be electrically connected between a first initialization line VIL1 receiving a first initialization voltage Vint1 and the third transistor T3. The fourth transistor T4 may include a source connected to the first initialization line VIL1, a drain connected to the first node NDI, and a gate connected to the third scan line GIi. The fourth transistor T4 may be turned on by the initialization scan signal GISi applied via the third scan line GIi. The fourth transistor T4 turned on by the initialization scan signal GISi may transmit the first initialization voltage Vint1 to the first node ND1, and may initialize the potential of the gate of the first transistor T1. In the present embodiment, the fourth transistor T4 may be defined as an initialization transistor.

The fifth transistor T5 may be electrically connected between the first voltage line VL1 receiving the first driving voltage ELVDD and the first transistor T1. The fifth transistor T5 may include a source connected to the first voltage line VL1, a drain connected to the second node ND2, and a gate connected to the light emission line ELi.

The sixth transistor T6 may be electrically connected between the first transistor T1 and the light emitting element OLED. The sixth transistor T6 may include a source connected to the third node ND3, a drain connected to the first electrode AE of the light emitting element OLED via a fourth node ND4, and a gate connected to the light emission line ELi.

The fifth transistor T5 and the sixth transistor T6 may be turned on by a light emission signal ESi applied via the light emission line ELi. The light emission duration of the light emitting element OLED may be controlled by the light emission signal ESi. When the fifth transistor T5 and the sixth transistor T6 are turned on, a driving current Id may be generated in accordance to a voltage difference between a gate voltage of the gate of the first transistor T1 and the first driving voltage ELVDD, and the driving current Id may be supplied to the light emitting element OLED via the sixth transistor T6, so that the light emitting element OLED may emit light. In the present embodiment, the fifth transistor T5 and the sixth transistor T6 may be defined as light emission control transistors.

The seventh transistor T7 may be electrically connected between the sixth transistor T6 and a second initialization line VIL2 receiving a second initialization voltage Vint2. The seventh transistor T7 may include a source connected to the fourth node ND4, a drain connected to the second initialization line VIL2, and a gate connected to a first scan line GWi-1. The gate of the seventh transistor T7 may be connected to an i-1-th write scan line GWi-1, which is a write scan line of the previous stage of the i-th write scan line GWi. However, the embodiment of the invention is not limited thereto, and the gate of the seventh transistor T7 may be electrically connected to a separate fourth scan line.

The seventh transistor T7 may be turned on by an i-1-th write scan signal GWSi-I applied via the first write scan line GWi-1. By the turned-on seventh transistor T7, the second initialization voltage Vint2 may be transmitted to the fourth node ND4. The second initialization voltage Vint2 may have the same level as the first initialization voltage Vint1, but without being limited thereto, may have a different level from the first initialization voltage Vint1. In the present embodiment, the seventh transistor T7 may be defined as an initialization transistor.

The seventh transistor T7 may improve the capability of the pixel PXij to express black. A portion of the driving current Id may exit as a bypass current through the seventh transistor T7 by the seventh transistor T7. When a black image is displayed, a current reduced by the amount of current of the bypass current exited from the driving current Id through the seventh transistor T7 may be provided to the light emitting element OLED, so that the black image may be clearly displayed. That is, an accurate black luminance image may be implemented by the seventh transistor T7, so that the contrast ratio of the display device DD (see FIG. 1) may be improved.

The capacitor CAP may include a first capacitor electrode receiving the first driving voltage ELVDD and a second capacitor electrode connected to the first node ND1. In the capacitor CAP, charges corresponding to a voltage difference between the first capacitor electrode and the second capacitor electrode may be stored. When the fifth transistor T5 and the sixth transistor T6 are turned on, the amount of current (e.g., electrical current) flowing in the first transistor T1 may be determined in accordance with a voltage stored in the capacitor CAP.

The configuration of the pixel driving circuit PDC illustrated in FIG. 5 is only exemplary, and the configuration of the pixel driving circuit PDC may be changed and implemented without being limited thereto.

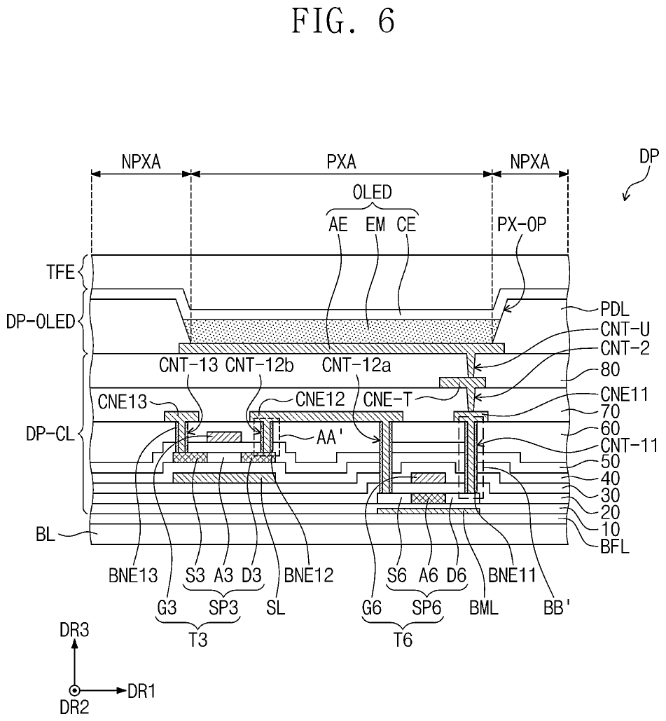

FIG. 6 is a cross-sectional view of a display panel DP according to an embodiment of the invention. FIG. 6 exemplarily illustrates the light emitting element OLED and some transistors T3 and T6 of the pixel circuit PDC (see FIG. 5) which are connected to the light emitting element OLED. The aforementioned description may be applied to the components of the display panel DP illustrated in FIG. 6.

Referring to FIG. 6, the display panel DP may include the base layer BL, and the circuit layer DP-CL, the display element layer DP-OLED and the encapsulation layer TFE in order from the base layer BL.

The base layer BL may provide a base surface on which the circuit layer DP-CL is disposed. The circuit layer DP-CL may include insulation layers BFL, and 10 to 80, the transistors T3 and T6, and connection electrodes CNE11 to CNE13, and CNE-T. The insulation layers BFL, and 10 to 80 may include a buffer layer BFL and first to eighth insulation layers 10 to 80 disposed on the buffer layer BFL. However, the insulation layers included in the circuit layer DP-CL are not limited thereto, and may vary depending on the configuration of a pixel driving circuit PDC included in the circuit layer DP-CL and the process of providing the circuit layer DP-CL. In an embodiment, one or more layers among insulation layers BFL and 10 to 80 may be collectively referred to as “an insulation layer.”

The buffer layer BFL may be disposed on the base layer BL. The buffer layer BFL may include at least one inorganic layer. For example, the buffer layer BFL may include at least one of aluminum oxide, titanium oxide, silicon oxide, silicon nitride, silicon oxynitride, zirconium oxide and hafnium oxide. The buffer layer BFL may improve the coupling force between a semiconductor pattern layer (e.g., a sixth semiconductor pattern SP6 or a conductive pattern layer) of the circuit layer DP-CL disposed on the base layer BL and the base layer BL.

Each of the first to eighth insulation layers 10 to 80 may include an inorganic layer and/or an organic layer, and may have a single-layered or multi-layered structure. The inorganic layer may include at least one of aluminum oxide, titanium oxide, silicon oxide, silicon nitride, silicon oxynitride, zirconium oxide and hafnium oxide. However, the material of the inorganic layer is not limited to the above examples. The organic layer may include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin and a perylene-based resin. However, the material of the organic layer is not limited to the above examples.

A light blocking pattern BML may be disposed on the buffer layer BFL. When the buffer layer BFL is omitted, the light blocking pattern BML may be directly disposed on a base layer BL. The light blocking pattern BML may include molybdenum. The light blocking pattern BML may perform a shielding function. The light blocking pattern BML may prevent an electric potential due to a polarization phenomenon between the insulation layers 10 to 80 disposed on the light blocking pattern BML from affecting the transistors T1 to T7 (see FIG. 5).

The sixth semiconductor pattern SP6 of a semiconductor layer may be disposed on the first insulation layer 10. The sixth semiconductor pattern SP6 may include a silicon semiconductor. For example, the sixth semiconductor pattern SP6 may include polysilicon or amorphous silicon. However, as long as the sixth semiconductor pattern has semiconductor properties, the material included in the sixth semiconductor pattern is not limited to the above examples.

Depending on whether doped or not, the sixth semiconductor pattern SP6 may include a plurality of regions having different electrical properties from each other. A first semiconductor pattern layer may include a first region having a high conductivity rate and a second region having a low conductivity rate. The first region may be doped with an N-type dopant or a P-type dopant. A P-type transistor may include a doped region which has been doped with the P-type dopant, and an N-type transistor may include a doped region which has been doped with the N-type dopant. The second region may be a non-doped region, or a region doped to a concentration lower than that of the first region.

The conductivity (e.g., electrical conductivity) of the first region is greater than the conductivity of the second region, and the first region may substantially serve as a source and a drain of a transistor. The second region may substantially correspond to a channel (or an active) of a transistor. That is, in the first semiconductor pattern layer, the first region having high conductivity may be a source or drain of a transistor or a connection signal line, and the second region having low conductivity may be a channel of the transistor.

The sixth semiconductor pattern SP6 may include a sixth source S6, a sixth channel A6, and a sixth drain D6. The sixth source S6 and the sixth drain D6 may be respectively extended from the sixth channel A6 in directions opposing each other. That is, the sixth source S6 and the sixth drain D6 may be spaced apart on a plane with the sixth channel A6 interposed therebetween.

The first insulation layer 10 may be disposed on the buffer layer BFL. The first insulation layer 10 may cover the light blocking pattern BML. The second insulation layer 20 may be disposed on the first insulation layer 10. The second insulation layer 20 may cover the sixth semiconductor pattern SP6.

A sixth gate electrode G6 may be disposed on the second insulation layer 20. The sixth gate electrode G6 may overlap the sixth channel A6. In an embodiment, the sixth gate electrode G6 may function as a mask in a process of doping the sixth semiconductor pattern SP6.

FIG. 6 exemplarily illustrates that the sixth transistor T6 has a top-gate structure in which the sixth gate electrode G6 is disposed in an upper portion of the sixth semiconductor pattern SP6, but the embodiment of the invention is not limited thereto, and the sixth transistor T6 may have a bottom-gate structure in which the sixth gate electrode G6 is disposed in a lower portion of the sixth semiconductor pattern SP6.

The aforementioned first, second, fifth, and seventh transistors T1, T2, T5, and T7 (see FIG. 5) may be transistors having the same configuration as the sixth transistor T6. For example, semiconductor patterns of the first, second, fifth, and seventh transistors T1, T2, T5, and T7 (see FIG. 5) may be formed from a first semiconductor pattern material layer in the same way as the sixth semiconductor pattern SP6, and gate electrodes of the first, second, fifth, and seventh transistors T1, T2, T5, and T7 (see FIG. 5) may be formed from the same conductive pattern material layer from which the sixth gate electrode G6 is formed. However, the embodiment of the invention is not necessarily limited thereto.

In an embodiment, where the semiconductor patterns are formed from a first semiconductor pattern material layer in the same way as the sixth semiconductor pattern SP6, such semiconductor patterns may be in a same layer as the sixth semiconductor patter SP6. Similarly, gate electrodes which are formed from the same conductive pattern material layer from which the sixth gate electrode G6 is provided, may be in a same layer as the sixth gate electrode G6. As being in a same layer, elements may be formed in a same process and/or include a same material as each other, elements may be respective portions of a same material layer, clements may be on a same layer by forming an interface with a same underlying or overlying layer, etc., without being limited thereto.

The third insulation layer 30 may be disposed on the second insulation layer 20. The third insulation layer 30 may cover the sixth gate electrode G6.

A scan line SL may be disposed on the third insulation layer 30. The scan line SL may correspond to some of the aforementioned first to third scan lines GWi, GCi, and GIi (scc FIG. 5).

The fourth insulation layer 40 may be disposed on the third insulation layer 30. The fourth insulation layer 40 may cover the scan line SL.

A third semiconductor pattern SP3 may be disposed on the fourth insulation layer 40. The third semiconductor pattern SP3 may include an oxide semiconductor including a metal oxide. The oxide semiconductor may include a metal oxide of such as zinc (Zn), indium (In), gallium (Ga), tin (Sn), or titanium (Ti), or a combination of a metal such as zinc (Zn), indium (In), gallium (Ga), tin (Sn), or titanium (Ti), and an oxide thereof. The oxide semiconductor may include indium-tin oxide (ITO), indium-gallium-zinc oxide (IGZO), zinc oxide (ZnO), indium-zinc oxide (IZO), zinc-indium oxide (ZIO), indium oxide (InO), titanium oxide (TiO), indium-zinc-tin oxide (IZTO), zinc-tin oxide (ZTO), or the like. However, the embodiment of the invention is not necessarily limited thereto.

Depending on whether the metal oxide is reduced or not, the third semiconductor pattern SP3 may include a plurality of regions having different electrical properties from each other. In the third semiconductor pattern SP3, a region in which the metal oxide has been reduced (hereinafter, a reduction region) may have higher conductivity than a region in which the metal oxide has not been reduced (hereinafter, a non-reduction region). The reduction region may substantially serve as a source or drain of a transistor. The non-reduction region may substantially correspond to a channel (or an active) of a transistor.

The third semiconductor pattern SP3 may include a third source S3, a third channel A3, and a third drain D3. The third source S3 and the third drain D3 may be respectively extended from the third channel A3 in directions opposing each other. That is, the third source S3 and the third drain D3 may be spaced apart on a plane with the third channel A3 interposed therebetween.

The fifth insulation layer 50 may be disposed on the fourth insulation layer 40. The fifth insulation layer 50 may cover the third semiconductor pattern SP3.

A third gate electrode G3 may be disposed on the fifth insulation layer 50. The third gate electrode G3 may overlap the third channel A3. In an embodiment, the third gate electrode G3 may function as a mask in a process of doping the third semiconductor pattern SP3.

The third semiconductor pattern SP3 may overlap a portion of the scan line SL disposed in a lower portion of the third semiconductor pattern SP3. The portion of the scan line SL overlapping the third semiconductor pattern SP3 may serve as a gate of the third transistor T3 together with the third gate electrode G3. In this case, a third gate of the third transistor T3 may be dually formed to have a sufficient amount of gate charges (e.g., electrical charges), and may be switched at a high speed. In addition, since the scan line SL is disposed overlapping the third semiconductor pattern SP3, it is possible to prevent the third semiconductor pattern SP3 from being damaged by light introduced from a lower portion of the display panel DP. However, the above structure of the third transistor T3 is only exemplary, and the embodiment of the invention is not limited thereto.

The aforementioned fourth transistor T4 (see FIG. 5) may be a transistor having the same structure as the third transistor T3. For example, a semiconductor pattern of the fourth transistor T4 (see FIG. 5) may be formed from a second semiconductor pattern material layer in the same way as the third semiconductor pattern SP3, and a gate electrode of the fourth transistor T4 (see FIG. 5) may be formed from the same conductive pattern material layer from which the third gate electrode G3 is formed. However, the embodiment of the invention is not necessarily limited thereto.

The third semiconductor pattern SP3 of the third transistor T3 and the sixth semiconductor pattern SP6 of the sixth transistor T6 may be disposed on (or in) different layers from each other, that is, being respective patterns of different material layers. However, this is only exemplary, and semiconductor patterns of all transistors included in the pixel driving circuit PDC (see FIG. 5) may be disposed on (or in) the same layer.

The sixth insulation layer 60 may be disposed on the fifth insulation layer 50. The sixth insulation layer 60 may cover the third gate electrode G3.

The connection electrodes CNE11 to CNE13 may be disposed on the sixth insulation layer 60. The connection electrodes CNE11 to CNE13 may each have a structure in which titanium (Ti)/aluminum (Al)/titanium (Ti) metal materials are sequentially stacked, such as along a thickness direction of the display panel DP. A thickness of the display device DD, the display panel DP and various components or layers thereof, may be defined along a third direction DR3 (e.g., a thickness direction).

The connection electrodes CNE11 to CNE13 may include 1-1 to 1-3 connection electrodes CNE11 to CNE13. The 1-1 to 1-3 connection electrodes CNE11 to CNE13 may be disposed spaced apart from each other along the sixth insulation layer 60. In FIG. 6, for convenience, the connection electrodes CNE11 to CNE13 are illustrated as having a flat upper surface by overlapping an entirety of contact-holes CNT-11, CNT-12, and CNT-13 on a plane. In an embodiment, the connection electrodes CNE11 to CNE13 may be disposed along inner surfaces of contact-holes CNT-11, CNT-12a, CNT-12b, and CNT-13.

Bridge electrodes BNE11, BNE12, and BNE13 may be disposed inside the contact-holes CNT-11, CNT-12, and CNT-13. The connection electrodes CNE11 to CNE13 may be electrically connected to electrode layers via the bridge electrodes BNE11, BNE12, and BNE13. The bridge electrodes BNE11, BNE12, and BNE13 may include a first bridge electrode BNE11, a second bridge electrode BNE12, and a third bridge electrode BNE13. Details thereof will be described later.

The 1-1 connection electrode CNE11 may be connected to the sixth drain D6 of the sixth transistor T6 via the first bridge electrode BNE11. The 1-1 connection electrode CNE11 may be connected to the sixth drain D6 via (or within) the contact-hole CNT-11 passing through the second to sixth insulation layers 20 to 60.

The 1-2 connection electrode CNE12 may be connected to the sixth source S6 of the sixth transistor T6 via the second bridge electrode BNE12. The 1-2 connection electrode CNE12 may be connected to the sixth source S6 via the contact-hole CNT-12a passing through the second to sixth insulation layers 20 to 60.

The 1-2 connection electrode CNE12 may be extended along a plane from the contact-hole CNT-12a, to overlap the third drain D3 of the third transistor T3. The 1-2 connection electrode CNE12 may be further connected to the third drain D3 via contact-hole CNT-12b passing through the fifth and sixth insulation layers 50 and 60. Accordingly, the third semiconductor pattern SP3 of the third transistor T3 and the sixth semiconductor pattern SP6 of the sixth transistor T6 disposed in different layers from each other may be electrically connected to each other through a same connection electrode (e.g., the 1-2 connection electrode CNE12).

The 1-3 connection electrode CNE13 may be connected to the third source S3 of the third transistor T3 via the third bridge electrode BNE13. The 1-3 connection electrode CNE13 may be connected to the third source S3 via the contact-hole CNT-13 passing through the fifth and sixth insulation layers 50 and 60.

The seventh insulation layer 70 may be disposed on the sixth insulation layer 60. The seventh insulation layer 70 may cover the 1-1 to 1-3 connection electrodes CNE11 to CNE13. The seventh insulation layer 70 may be an organic layer.

An upper connection electrode CNE-T may be disposed on the seventh insulation layer 70. In addition, although not separately illustrated, some of signal lines included in the display panel DP may be formed from a same conductive pattern material layer in the circuit layer DP-CL.

The upper connection electrode CNE-T may be connected to the 1-1 connection electrode CNE11 via an upper contact-hole CNT-2 passing through the seventh insulation layer 70. Although FIG. 6 illustrates that the width of the upper contact-hole CNT-2 passing through the seventh insulation layer 70 is narrower than the width of the contact-hole CNT-12 passing through the fifth and sixth insulation layers 50 and 60, in an embodiment of the invention, the width of the upper contact-hole CNT-2 passing through the seventh insulation layer 70 may be greater than the width of the contact-hole CNT-12 passing through the fifth and sixth insulation layers 50 and 60. Here, a width of an element such as a contact-hole, may be defined along a plane. The width may be defined at various locations along a thickness or height of the element. A representative width of the element may be a maximum width, a minimum width or a width therebetween.

Although not illustrated, when a plurality of upper contact-holes CNT-2 passing through the seventh insulation layer 70 are provided, a separation distance between the upper contact-holes CNT-2 passing through the seventh insulation layer 70 may be greater than a separation distance between contact-holes CNT-12 passing through the fifth and sixth insulation layers 50 and 60. Accordingly, the width of the upper contact-hole CNT-2 passing through the seventh insulation layer 70 may be greater than the width of the contact-hole CNT-12 passing through the fifth and sixth insulation layers 50 and 60.

The upper connection electrode CNE-T may be connected to the sixth drain D6 of the sixth transistor T6 via the 1-1 connection electrode CNE11. However, the embodiment of the invention is not limited thereto, and the upper connection electrode CNE-T may be omitted, or an additional connection electrode disposed between the upper connection electrode CNE-T and the 1-1 connection electrode CNE11 may be further disposed in the circuit layer DP-CL.

The eighth insulation layer 80 may be disposed on the seventh insulation layer 70. The eighth insulation layer 80 may cover the upper connection electrode CNE-T. In the present specification, the eighth insulation layer 80 may be an organic layer.

At least one of the seventh insulation layer 70 and the eighth insulation layer 80 may include an organic layer. The organic layer may provide a flat surface by covering steps between particles present on the surface of a layer disposed in a lower portion of the organic layer or between components disposed in a lower portion, such as to planarize the surface. In addition, the organic layer may relieve stress between components disposed in upper and lower portions.

The display element layer DP-OLED may be disposed on the circuit layer DP-CL. The display element layer DP-OLED may include a pixel definition film PDL and the light emitting elements OLED. Each of the light emitting elements OLED may include the first electrode AE, a light emitting layer EM, and the second electrode CE.

The light emitting elements OLED may include an organic light emitting element, a quantum dot light emitting element, a micro-LED light emitting element, or a nano-LED light emitting element. However, the embodiment of the invention is not limited thereto, and the light emitting elements OLED may include various embodiments as long as light is generated in response to an electrical signal, or the amount of light is controlled.

Each of the light emitting elements OLED may be electrically connected to a transistor of a corresponding pixel drive circuit PDC (see FIG. 5). FIG. 6 exemplarily illustrates that each of the light emitting elements OLED is electrically connected to a corresponding sixth transistor T6.

The first electrodes AE of the light emitting elements OLED may be disposed on the uppermost layer of the circuit layer DP-CL. For example, the first electrodes AE may be disposed on the eighth insulation layer 80. The first electrodes AE may be disposed spaced apart along the eighth insulation layer 80. Each of the first electrodes AE may be connected to a corresponding upper connection electrode CNE-T via a contact-hole CNT-U passing through the eighth insulation layer 80. Each of the first electrodes AE may be electrically connected to the sixth drain D6 via the corresponding upper connection electrode CNE-T together with the 1-1 connection electrode CNE11.

The pixel definition film PDL may be disposed on the uppermost layer of the circuit layer DP-CL. For example, the pixel definition film PDL may be disposed on the eighth insulation layer 80. In the pixel definition film PDL, light emission openings PX-OP overlapping each of the first electrodes AE and exposing a portion of a corresponding first electrode AE to outside the pixel definition film PDL may be defined. A solid portion of the pixel definition film PDL may define the light emission openings PX-OP.

In the present embodiment, areas of the first electrodes AE which are exposed by the light emission openings PX-OP may correspond to light emitting regions PXA. That is, the display region DA (see FIG. 4) of the display panel DP may include light emitting regions PXA. A region (or planar area) in which a solid portion or a material portion of the pixel definition film PDL is disposed may correspond to a non-light emitting region NPXA. On a plane, the non-light emitting region NPXA is adjacent to the light emitting regions PXA, such as to surround the light emitting regions PXA, and may set the boundary of the light emitting regions PXA relative to the non-light emitting region NPXA.

The pixel definition film PDL as pixel defining layer may include a polymer resin. For example, the pixel definition film PDL may include a polyacrylate-based resin or a polyimide-based resin. Without being limited thereto, the pixel definition film PDL may further include an inorganic material.

The pixel definition film PDL may further include a light absorbing material. For example, the pixel definition film PDL may include a black coloring agent such as a black dye or a black pigment. For example, the black coloring agent may include carbon black, a metal such as chromium, or an oxide thereof. However, the embodiment of the invention is not necessarily limited thereto.

The light emitting layer EM may be disposed on the first electrode AE. The light emitting layers EM of the light emitting elements OLED may be disposed corresponding to the light emission openings PX-OP, respectively, and may be formed as light emitting patterns spaced apart on a plane. The patterns may be a discrete shape along the plane. However, without being limited thereto, the light emitting layers EM of the light emitting clements OLED may be formed as a common layer by being formed as a single film across pixels PX. The light emitting layer EM may include an organic light emitting material and/or an inorganic light emitting material. For example, the light emitting layer EM may include a fluorescent material, a phosphorescent material, an organometallic complex light emitting material, or a quantum dot. The light emitting layer EM may emit color light of any one of red, green, and blue colors.

The second electrode CE may be disposed on the light emitting layer EM. The second electrode CE of the light emitting elements OLED may be provided as a common layer of a single body, and may overlap both of the light emitting regions PXA and the non-light emitting region NPXA. The second electrode CE is commonly disposed in the pixels PX (sec FIG. 4), and may be provided with a common voltage.

The light emitting elements OLED may further include a light emission control layer disposed between the first electrode AE and the second electrode CE. For example, the light emission control layer may include a hole control layer disposed between the first electrode AE and the light emitting layer EM, or an electron control layer disposed between the light emitting layer EM and the second electrode CE. The hole control layer may include a hole injection layer, a hole transport layer, or an electron blocking layer, and the electron control layer may include an electron injection layer, an electron transport layer, or a hole blocking layer.

The encapsulation layer TFE may be disposed on the display element layer DP-OLED. The encapsulation layer TFE may seal the light emitting elements OLED. The encapsulation layer TFE may include at least one thin film of an inorganic film and an organic film. In an embodiment, the encapsulation layer TFE may include inorganic films and an organic film which is disposed between the inorganic films.

The inorganic film of the encapsulation layer TFE may protect the light emitting elements OLED from moisture and/or oxygen. The inorganic film may include at least one of aluminum oxide, titanium oxide, silicon oxide, silicon nitride, silicon oxynitride, zirconium oxide and hafnium oxide. However, the material of the inorganic film is not limited to the above examples.

The organic film of the encapsulation layer TFE may protect the light emitting elements OLED from foreign substances such as dust particles. The organic film may include an acrylic resin. However, the material of the organic film is not limited to the above example.

The first driving voltage ELVDD (see FIG. 5) may be applied to the first electrode AE, and the second driving voltage ELVSS (see FIG. 5) may be applied to the second electrode CE. A hole and an electron injected into the light emitting layer EM are combined to form an exciton, and when the exciton transits to a ground state, the light emitting elements OLED may emit light. Since the light emitting elements OLED emit light in response to an electrical signal applied thereto, the display panel DP may display an image IM through the display region DA (see FIG. 4).

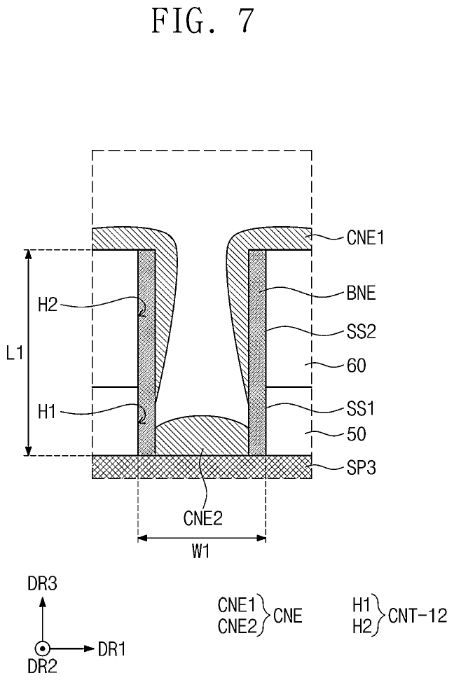

FIG. 7 is an enlarged view of region AA′ of FIG. 6. Specifically, FIG. is a view showing the contact-hole CNT-12, the 1-2 connection electrode CNE12, and the second bridge electrode BNE12. Hereinafter, for convenience of description, the 1-2 connection electrode CNE12 will be referred to as a connection electrode CNE, and the second bridge electrode BNE12 will be referred to as a bridge electrode BNE.

Referring to FIG. 7, the connection electrode CNE and the bridge electrode BNE may be connected to the third semiconductor pattern SP3 within the contact-hole CNT-12 passing through the fifth and sixth insulation layers 50 and 60 as a collective insulating layer. As passing through a layer, a hole or opening may extend through an entire thickness of the layer, such that the hole or opening is open at both an upper surface and a lower surface of the layer. The connection electrode CNE may be electrically connected to the third semiconductor pattern SP3 via the bridge electrode BNE disposed on side surfaces of the fifth and sixth insulation layers 50 and 60. In the present specification, the fifth insulation layer 50 may be referred to as a “first insulation layer,” and the sixth insulation layer 60 may be referred to as a “second insulation layer.”

The material included in the fifth insulation layer 50 as a first thickness portion of a collective insulating layer is different from the material included in the sixth insulation layer 60 as a second thickness portion of the collective insulating layer. The fifth insulation layer 50 includes silicon oxide, and the sixth insulation layer 60 includes silicon nitride. The fifth insulation layer 50 may be composed of silicon oxide, and the sixth insulation layer 60 may be composed of silicon nitride.

The contact-hole CNT-12 may include a first hole H1 (e.g., a first hole portion) defined by the fifth insulation layer 50 together with a second hole H2 (e.g., a second hole portion) defined by the sixth insulation layer 60. The first hole H1 and the second hole H2 may be aligned with each other. The first hole H1 may be defined by a first side surface SS1 of the fifth insulation layer 50, and the second hole H2 may be defined by a second side surface SS2 of the sixth insulation layer 60. The first side surface SS1 and the second side surface SS2 may be coplanar with each other. The first hole H1 may expose at least a portion of an upper surface of the third semiconductor pattern SP3 to outside the fifth insulation layer 50. A virtual center line of the first hole Hl and a virtual center line of the second hole H2 may be substantially the same. The first hole H1 and the second hole H2 may be aligned in one column along the thickness direction.

In an embodiment, the size of the first hole H1 and the size of the second hole H2 are equal to each other. The size may refer to a planar size, such as a dimension along a plane. The respective sizes of the first hole Hl and the size of the second hole H2 may be constant along a direction in which the contact-hole CNT-12 is extended, that is, a third direction DR3. The shape of the first hole Hl and the shape of the second hole H2 are not limited thereto, and may have different sizes or dimension along the plane, at various positions along the third direction DR3.

A width W1 of the contact-hole CNT-12 may be about 0.5 micrometer (um) to about 2 micrometers (um). For example, the width W1 of the contact-hole CNT-12 may be about 1 um to about 1.8 um. The width W1 of the contact-hole CNT-12 may be constant along the direction in which the contact-hole CNT-12 is depressed, that is, along an entirety of the third direction DR3.

A recession depth LI of the contact-hole CNT-12 may be about 1 um or greater. For example, the recession depth LI of the contact-hole CNT-12 may be about 1 um to about 1.5 um. The recession depth LI may be a total depth of the contact-hole CNT-12, including a sum of thicknesses of the fifth and sixth insulation layers 50 and 60.

The bridge electrode BNE may be disposed on the side surfaces SS1 and SS2 of the insulation layers 50 and 60. The bridge electrode BNE may directly contact the third semiconductor pattern SP3. The bridge electrode BNE is disposed along the side surfaces SS1 and SS2 of the insulation layers 50 and 60, and thus, may extend perpendicular or normal to the third semiconductor pattern SP3. The uppermost surface of the bridge electrode BNE may be coplanar with the upper surface of the insulating layer which is defined by the upper surface of the sixth insulation layer 60.

The thickness of the bridge electrode BNE in the first direction DR1 is illustrated to be constant at various positions along the third direction DR3, but the embodiment of the invention is not limited thereto, and the thickness of the bridge electrode BNE may vary at positions along the third direction DR3. For example, the thickness of the bridge electrode BNE which is taken in a direction normal to a respective inner side surface of a layer, may gradually decrease in a direction opposite to the recession direction of the contact-hole CNT-12, that is, the third direction DR3. That is, the thickness may decrease as a distance to the semiconductor layer decreases. The thickness may be maximum at an upper surface of the collective insulating layer. The length of the bridge electrode BNE which is defined along the thickness direction may be equal to the recession depth LI of the contact-hole CNT-12.

The connection electrode CNE may include a first connection electrode CNE1 (e.g., a first electrode portion) disposed on an upper surface of the sixth insulation layer 60 and on the bridge electrode BNE and extended into the respective contact-hole, and a second connection electrode CNE2 (e.g., a second electrode portion) disposed on the third semiconductor pattern SP3 and disconnected from the first electrode portion. The first connection electrode CNE1 and the second connection electrode CNE2 may include the same material as each other. For example, the first connection electrode CNE1 and the second connection electrode CNE2 may each have a structure in which titanium (Ti)/aluminum (Al)/titanium (Ti) metal materials are sequentially stacked.

According to an embodiment of the invention, the bridge electrode BNE may include a material different from that of the first connection electrode CNE1 and of the second connection electrode CNE2. For example, when the bridge electrode BNE contacts the third semiconductor pattern SP3, the bridge electrode BNE may include an n-type dopant. However, without being limited thereto, the material constituting the bridge electrode BNE may vary depending on an object (e.g., a semiconductor pattern or a metal layer) electrically connected to the connection electrode CNE. For example, the bridge electrode BNE may include a p-type dopant, or may include amorphous silicon (a-Si) or polysilicon.

The first connection electrode CNE1 and the second connection electrode CNE2 may be disposed spaced apart from each other. The various electrode portions may be disconnected from each other at a location along an inner sidewall of the insulating layer. The first connection electrode CNE1 and the second connection electrode CNE2 may be electrically connected to each other via the bridge electrode BNE. The first connection electrode CNE1 may be disposed spaced apart from the third semiconductor pattern SP3. The first connection electrode CNE1 and the third semiconductor pattern SP3 may be electrically connected to each other via the bridge electrode BNE. That is, the first connection electrode CNE1 may be directly and electrically connected to the third semiconductor pattern SP3 via the bridge electrode BNE, or may be connected to the second connection electrode CNE2 via the bridge electrode BNE, and electrically connected to the third semiconductor pattern SP3 which is electrically connected to the second connection electrode CNE2.

When the display device DD has high resolution, the planar width of the connection electrode CNE and the planar width of the contact-hole CNT-12 are reduced to configure a pixel layout within a limited pixel pitch. When the width of the contact-hole CNT-12 is reduced, due to a problem of step coverage in a process, the connection electrode CNE may include the first connection electrode CNE1 and the second connection electrode CNE2 disposed spaced apart from each other (e.g., separated from each other). However, when the bridge electrode BNE is disposed extended along inner side surfaces of the insulation layers 50 and 60 which define the contact-hole CNT-12, the first connection electrode CNE1 and the second connection electrode CNE2 may be electrically connected to each other via the bridge electrode BNE. As a result, even if the number of signal lines increases, and the degree of integration of a circuit increases, the first connection electrode CNE1 and the second connection electrode CNE2 separated from each other are electrically connected to each other and function as a single connection electrode, so that the display device DD of the invention may have high-resolution, high-speed driving, and high-robustness properties.

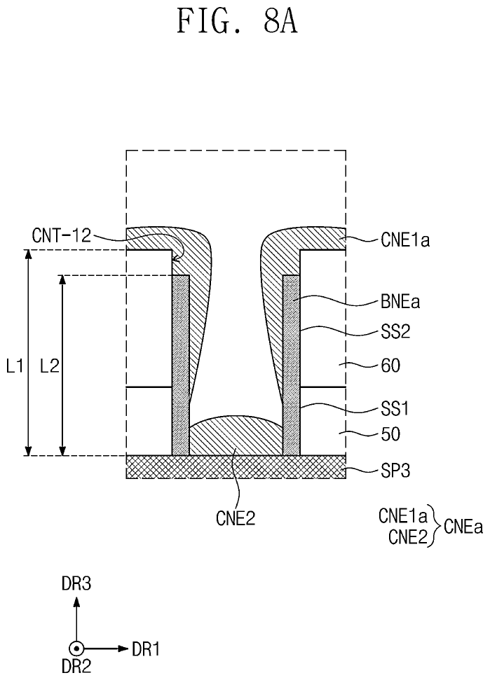

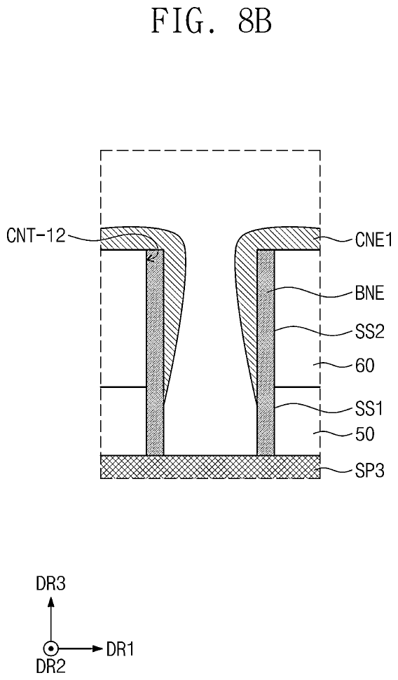

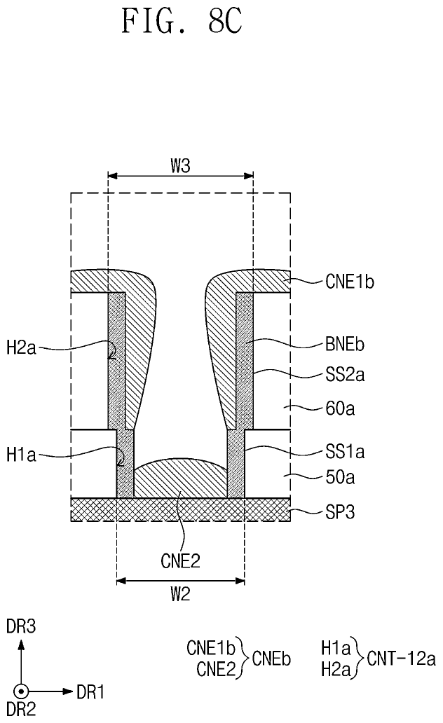

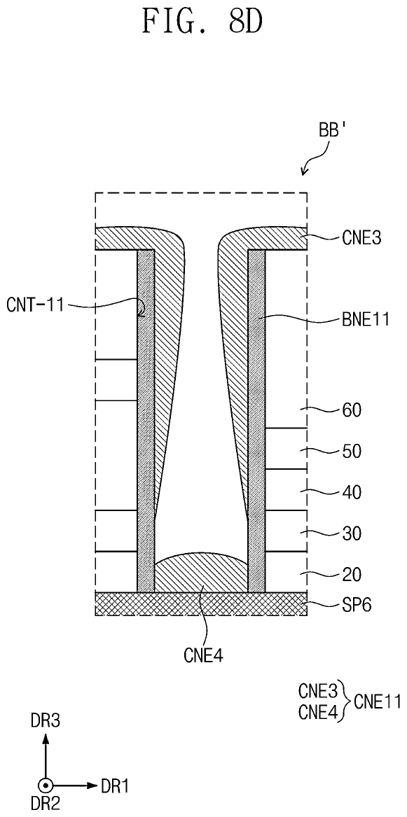

FIG. 8A to FIG. 8C are enlarged views of a display device DD according to an embodiment of the invention. The same features as those described above will be briefly described or omitted.

Referring to FIG. 8A, a bridge electrode BNEa may be disposed on a portion of the side surfaces SS1 and SS2 of the insulation layers 50 and 60. Specifically, the bridge electrode BNEa may be disposed on a portion of the first side surface SS1 of the fifth insulation layer 50 and on a portion of the second side surface SS2 of the sixth insulation layer 60. A length L2 of the bridge electrode BNEa in the third direction DR3 may be smaller than the recession depth LI of the contact-hole CNT-12. That is, the uppermost surface of the bridge electrode BNEa may be spaced apart from the upper surface of the insulating layer which is defined by the upper surface of the sixth insulation layer 60.

A connection electrode CNEa may include a first connection electrode CNE1a disposed on the upper surface of the sixth insulation layer 60, the portion of the second side surface SS2 and the bridge electrode BNEa, and a second connection electrode CNE2 disposed on the third semiconductor pattern SP3. The first connection electrode CNE1a and the second connection electrode CNE2 may include the same material. For example, the first connection electrode CNE1a and the second connection electrode CNE2 may have a structure in which titanium (Ti)/aluminum (Al)/titanium (Ti) metal materials are sequentially stacked. The bridge electrode BNEa may include a material different from that of the first connection electrode CNE1a and of the second connection electrode CNE2. For example, the bridge electrode BNEa may include an n-type dopant.

The first connection electrode CNE1a and the second connection electrode CNE2 may be disposed spaced apart from each other. The first connection electrode CNE1a and the second connection electrode CNE2 may be electrically connected to each other via the bridge electrode BNEa.

Referring to FIG. 8B, a connection electrode portion may not be disposed in direct contact with the third semiconductor pattern SP3. The connection electrode CNE illustrated in FIG. 7 includes the first connection electrode CNE1 disposed on the upper surface of the sixth insulation layer 60 and on the bridge electrode BNE, and the second connection electrode CNE2 disposed on the third semiconductor pattern SP3. In contrast, in FIG. 8B, the second connection electrode CNE2 may be omitted. In this case, the connection electrode CNE may include only the first connection electrode CNE1.

The first connection electrode CNE1 may be disposed spaced apart from the third semiconductor pattern SP3 and a portion of the first side surface SS1 may be exposed to outside the contact-hole CNT-12 at an area between the first connection electrode CNE1 and the third semiconductor pattern SP3. Here, the area may be defined in a DR3-DR2 plane. The first connection electrode CNE1 and the third semiconductor pattern SP3 may be electrically connected to each other via the bridge electrode BNE in contact with each of the first connection electrode CNE1 and the third semiconductor pattern SP3. That is, the first connection electrode CNE1 may be electrically connected to the third semiconductor pattern SP3 via the bridge electrode BNE.

Referring to FIG. 8C, the contact-hole CNT-12a may include a first hole H1a (e.g., a first hole portion) defined by a first side surface SS1a of a fifth insulation layer 50a, and a second hole H2a (e.g., a second hole portion) defined by a second side surface SS2a of a sixth insulation layer 60a. A second width W2 of the first hole H1a and a third width W3 of the second hole H2a may be different from each other. For example, the third width W3 of the second hole H2a may be greater than the second width W2 of the first hole H1a. The difference between the third width W3 of the second hole H2a and the second width W2 of the first hole H1a may be about 0.2 um or greater. For example, the difference in the first direction DR1 between the third width W3 of the second hole H2a and the second width W2 of the first hole H1a may be about 0.2 um to about 0.3 um. However, the difference between the third width W3 of the second hole H2a and the second width W2 of the first hole H1a is not limited to the above numerical range, and the difference between the third width W3 of the second hole H2a and the second width W2 of the first hole H1a may occur depending on the materials of the fifth insulation layer 50a and the sixth insulation layer 60a, an etching method used in a process of forming a respective contact-hole, or the like, and may have various values accordingly.

A bridge electrode BNEb may be directly and commonly disposed on the first side surface SS1a and the second side surface SS2a. The bridge electrode BNEb may directly contact the third semiconductor pattern SP3. The bridge electrode BNEb is disposed along the first side surface SS1a and the second side surface SS2a, and thus, may include a step in accordance with the difference between the third width W3 of the second hole H2a and the second width W2 of the first hole H1a. The thickness of the bridge electrode BNEb which is taken in a direction normal to the various inner side surfaces of the insulating layers, may have a constant value at various positions along the contact-hole CNT-12a (e.g., along the third direction DR3).

A first connection electrode CNE1b and the second connection electrode CNE2 may be disposed spaced apart from each other. The first connection electrode CNE1b and the third semiconductor pattern SP3 may be electrically connected to each other via the bridge electrode BNEb. That is, the first connection electrode CNE1b may be directly and electrically connected to the third semiconductor pattern SP3 via the bridge electrode BNEb, or may be connected to the second connection electrode CNE2 via the bridge electrode BNEb, and electrically connected to the third semiconductor pattern SP3 which is electrically connected to the second connection electrode CNE2.

FIG. 8D is an enlarged view of region BB′ of FIG. 6. Specifically, FIG. 8D is a view showing the contact-hole CNT-11, the 1-1 connection electrode CNE11, and the first bridge electrode BNE11 of FIG. 6.

Referring to FIG. 8D, the 1-1 connection electrode CNE11 and the first bridge electrode BNE11 may be connected to the sixth semiconductor pattern SP6 via the contact-hole CNT-11 passing through the second to sixth insulation layers 20, 30, 40, 50, and 60. Specifically, the 1-1 connection electrode CNE11 may include a third connection electrode CNE3 as a third electrode portion disposed on the upper surface of the sixth insulation layer 60 and on the first bridge electrode BNE11, and a fourth connection electrode CNE4 as a fourth electrode portion disposed on the sixth semiconductor pattern SP6. The third connection electrode CNE3 and the fourth connection electrode CNE4 may each have a structure in which titanium (Ti)/aluminum (Al)/titanium (Ti) metal materials are sequentially stacked.

According to an embodiment of the invention, the first bridge electrode BNE11 may include a material different from that of the third connection electrode CNE3 and of the fourth connection electrode CNE4. For example, when the first bridge electrode BNE11 contacts the sixth semiconductor pattern SP6, the first bridge electrode BNE11 may include a p-type dopant. However, without being limited thereto, the material constituting the first bridge electrode BNE11 may vary depending on an object (e.g., a semiconductor pattern or a metal layer) electrically connected to the 1-1 connection electrode CNE11. For example, the bridge electrode BNE may include an n-type dopant, or may include amorphous silicon (a-Si) or polysilicon.

The third connection electrode CNE3 and the fourth connection electrode CNE4 may be disposed spaced apart from each other. The third connection electrode CNE3 and the fourth connection electrode CNE4 may be electrically connected to each other via the first bridge electrode BNE11. The third connection electrode CNE3 may be disposed spaced apart from the sixth semiconductor pattern SP6. The third connection electrode CNE3 and the sixth semiconductor pattern SP6 may be electrically connected to each other via the first bridge electrode BNE11.

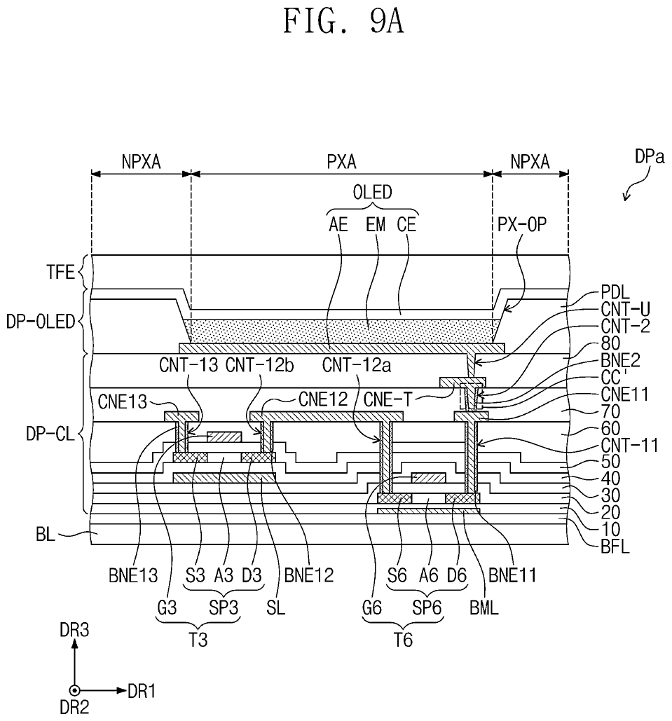

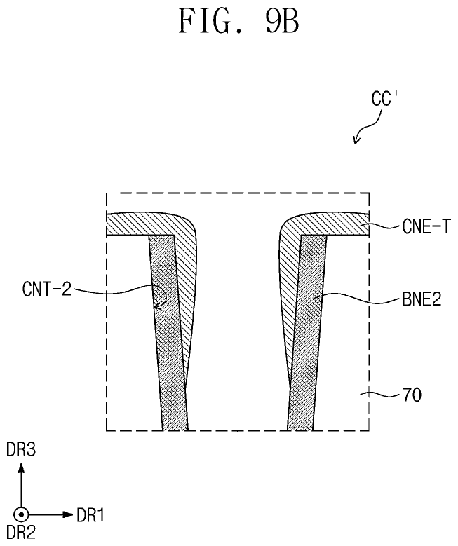

FIG. 9A is a cross-sectional view of a display panel Dpa according to an embodiment of the invention. FIG. 9B is an enlarged view of region CC′ of FIG. 9A. Redundant descriptions of the components of a display panel DPa illustrated in FIG. 9A will be omitted.

Referring to FIG. 9A, an upper bridge electrode BNE2 may be disposed in the upper contact-hole CNT-2. The upper connection electrode CNE-T may be connected to the 1-1 connection electrode CNE11 via the upper contact-hole CNT-2 passing through the seventh insulation layer 70. Specifically, the upper connection electrode CNE-T may be connected to the 1-1 connection electrode CNE11 via the upper bridge electrode BNE2.

FIG. 9B is an enlarged view of the upper contact-hole CNT-2, the upper connection electrode CNE-T, and the upper bridge electrode BNE2 of FIG. 9A. Referring to FIG. 9A and FIG. 9B, the upper bridge electrode BNE2 may be disposed on a side surface of the seventh insulation layer 70 which defines the upper contact-hole CNT-2. The upper bridge electrode BNE2 may directly contact the 1-1 connection electrode CNE11. The upper bridge electrode BNE2 may be disposed along the side surface of the seventh insulation layer 70.

The upper connection electrode CNE-T may be disposed on the upper surface of the seventh insulation layer 70, extend into the upper contact-hole CNT-2 and along the upper bridge electrode BNE2. According to an embodiment of the invention, the upper bridge electrode BNE2 may include a material different from that of the upper connection electrode CNE-T. For example, the upper bridge electrode BNE2 may include amorphous silicon (a-Si) or polysilicon.

The upper connection electrode CNE-T and the 1-1 connection electrode CNE11 may be disposed spaced apart from each other, along the sidewall of the seventh insulation layer 70. The upper connection electrode CNE-T and the 1-1 connection electrode CNE11 may be electrically connected to each other via the upper bridge electrode BNE2. While the upper bridge electrode BNE2 in FIGS. 9A and 9B is shown as being coplanar with the upper surface of the seventh insulation layer 70, the upper bridge electrode BNE2 may have a form similar to those of FIG. 8A or 8C, without being limited thereto.

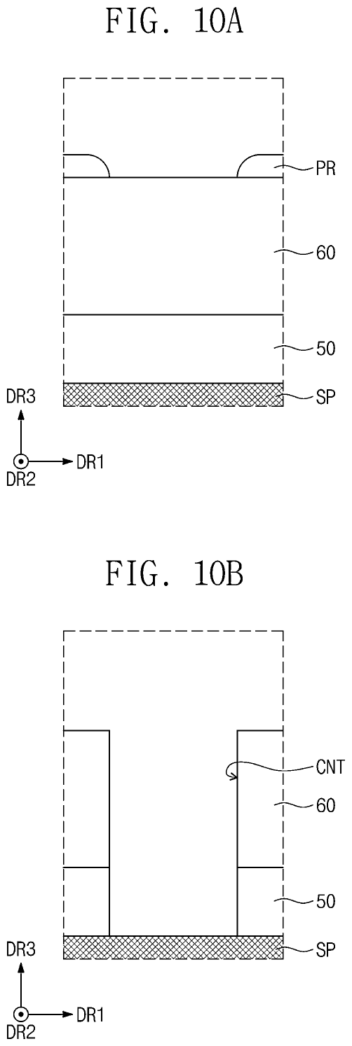

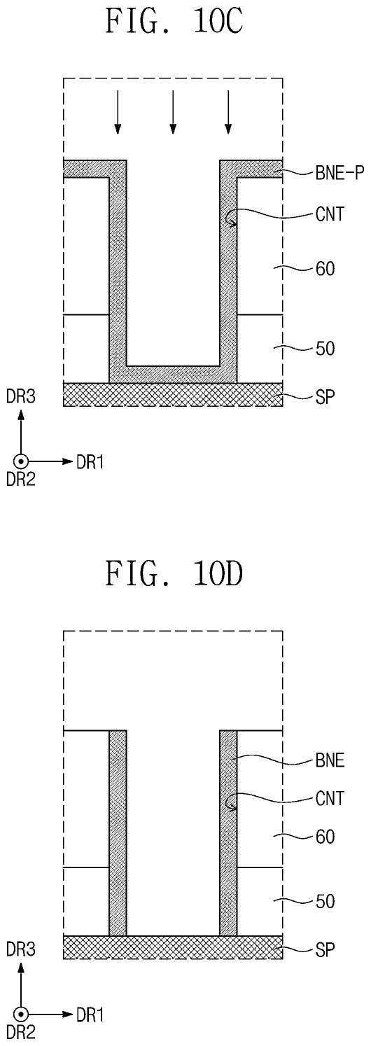

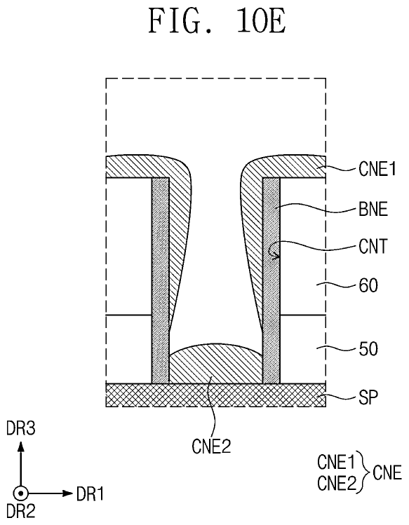

FIG. 10A to FIG. 10E are cross-sectional views showing structures of sequential processes in a method for manufacturing (or providing) a display device DD according to an embodiment of the invention.

Referring to FIG. 10A and FIG. 10B, a method for manufacturing (or providing) a display device DD according to an embodiment of the invention may include providing a semiconductor pattern SP of a transistor, a first insulation layer 50 disposed on the semiconductor pattern SP and a second insulation layer 60 disposed on the first insulation layer 50, and forming (or providing) a contact-hole CNT in an insulation layer including thickness portions of both the first insulation layer 50 and the second insulation layer 60. In the present specification, the semiconductor pattern SP may mean the third semiconductor pattern SP3 of a semiconductor layer described above with reference to FIG. 7 or the sixth semiconductor pattern SP6 of a semiconductor layer described above with reference to FIG. 8D, or may mean another electrode having conductivity, or the like. In addition, the contact-hole CNT may mean the contact-hole CNT-12 in FIG. 7, or the contact-hole CNT-11 in FIG. 8D. That is, the semiconductor pattern SP represents a first conductive pattern exposed at a bottom of a contact-hole and to which a second conductive pattern is electrically connected by a bridge conductive pattern.

The forming of the contact-hole CNT may include forming a photoresist pattern PR on the second insulating layer 60. Thereafter, the forming of the contact-hole CNT may include performing an etching process to the first insulation layer 50 and the second insulation layer 60. The etching process for the first insulation layer 50 and the second insulation layer 60 may include a plasma etching process which is performed by using the photoresist pattern PR as a mask. As the contact-hole CNT is formed, at least a portion of an upper surface of the semiconductor pattern SP may be exposed to outside the insulation layer. Sidewalls of the insulation layer define the contact-hole CNT. An upper surface of the insulation layer may be a surface which is furthest from the exposed conductive pattern. The photoresist pattern PR may be removed from the upper surface of the insulation layer to expose the upper surface to outside the stacked structure shown in FIG. 10B.

Referring to FIG. 10C and FIG. 10D, the method for manufacturing a display device DD according to an embodiment of the invention may include forming a bridge electrode BNE inside the contact-hole CNT. In the present specification, the bridge electrode BNE may mean the second bridge electrode BNE12 in FIG. 7, or the first bridge electrode BNE11 in FIG. 8D.

The forming of the bridge electrode BNE may include forming a preliminary bridge electrode BNE-P of a bridge electrode material layer on an upper surface of the second insulation layer 60, extending into the contact-hole CNT, along a side surface of the second insulation layer 60 and a side surface of the fifth insulation layer 50 and the semiconductor pattern SP, and etching the preliminary bridge electrode BNE-P.

The forming of the preliminary bridge electrode BNE-P may include a chemical vapor deposition (CVD) method of a silicon (Si)-based gas containing a low-concentration n-type dopant to have a constant electrical resistance. For example, the preliminary bridge electrode BNE-P may be formed by depositing silicon (Si) containing an n-type dopant on the upper surface of the second insulation layer 60, the side surface of the second insulation layer 60, and the semiconductor pattern SP by a method such as plasma enhanced chemical vapor deposition (PECVD), atmospheric-pressure CVD (APCVD), low-pressure CVD (LPCVD), or the like.

The preliminary bridge electrode BNE-P may have a constant thickness in the third direction DR3. The thickness may be defined in a direction normal to the profile of the underlying stacked structure, that is, normal to the upper surface of the insulation layer, normal to the side surfaces which define the contact-hole CNT and normal to the upper surface of the exposed second conductive pattern at the bottom of the contact-hole CNT. However, the embodiment of the invention is not limited thereto, and the thickness of the preliminary bridge electrode BNE-P in the third direction DR3 may gradually decrease along a recession direction of the contact-hole CNT. That is, the thickness of the bridge electrode material layer layer decrease as a distance from the upper surface of the insulation layer increases along the thickness direction of the display device DD.

The etching of the preliminary bridge electrode BNE-P may include a plasma etching process. By performing the plasma etching on the preliminary bridge electrode BNE-P, a portion of the preliminary bridge electrode BNE-P which extends along the upper surface of the second insulation layer 60 and a portion of the preliminary bridge electrode BNE-P which extends along the upper surface of the semiconductor pattern SP may be removed. Accordingly, the bridge electrode BNE formed on only side surfaces of the insulation layers 50 and 60 may be provided. Depending on the time and intensity of the plasma etching process, the length of the bridge electrode BNE along the thickness direction may be formed smaller than the recession depth of the contact-hole CNT.

Referring to FIG. 10E, the method for manufacturing a display device DD according to an embodiment of the invention may include forming a connection electrode CNE inside the contact-hole CNT. In the present specification, the connection electrode CNE may mean the above-described connection electrode CNE of FIG. 7. The forming of the connection electrode CNE may include disposing the connection electrode CNE in the contact-hole CNT and on the second insulation layer 60.

The connection electrode CNE may be formed by deposition in the contact-hole CNT and on the second insulation layer 60. For example, the connection electrode CNE may be formed by a sputtering process. The connection electrode CNE may include a conductive material. The connection electrode CNE is formed by the sputtering process, and thus, due to a narrow width of the contact-hole CNT, may be separately formed into a first connection electrode CNE1 disposed on the upper surface of the second insulation layer 60 and on the bridge electrode BNE12, and a second connection electrode CNE2 which disposed on the semiconductor pattern SP and disconnected from the first connection electrode CNE1. That is, due to a problem of step coverage caused by the sputtering process, a disconnection of a material layer for providing the connection electrode CNE1 is generated, so that the first connection electrode CNE1 and the second connection electrode CNE2 spaced apart from each other may be formed from a same material layer. In an embodiment, the providing of the first connection electrode CNE1 and the second connection electrode CNE2 are simultaneously performed with each other, such that the first connection electrode CNE1 and the second connection electrode CNE2 are respective portions of a same material layer.

As shown in FIG. 10E, the first connection electrode CNE1 includes portions which extend from the upper surface of the insulation layer and along the side surface thereof. The portions are spaced apart from each other at the upper surface of the insulation layer and along the contact-hole CNT, to define an upper hole in the first connection electrode CNE1. A size of the hole may be defined between facing inner surfaces of the portions and have a size along a planar direction. A size of the upper hole defined by the portions of the first connection electrode CNE1 increases in a direction from the upper surface of the insulation layer to the portion of the transistor which is exposed to outside of the insulation layer (e.g., in a direction opposite to the third direction DR3 shown in FIG. 10E).

However, since the bridge electrode BNE is disposed on the side surfaces of the insulation layers 50 and 60, the first connection electrode CNE1 and the second connection electrode CNE2 disposed spaced apart from each other may be electrically connected to each other. As a result, even if the number of signal lines increases, and the degree of integration of a circuit increases, the first connection electrode CNE1 and the second connection electrode CNE2 which are physically disconnected from each other are electrically connected to each other, so that the display device DD (see FIG. 6) of the invention may have high-resolution, high-speed driving, and high-robustness properties.

A display device DD of the invention may include a first connection electrode CNE1 and a second connection electrode CNE2 which are disposed physically spaced apart from each other in a contact-hole CNT. However, when a bridge electrode BNE is disposed along a side surface of an insulation layer defining the contact-hole CNT, the first connection electrode CNE1 and the second connection electrode CNE2 may be electrically connected to each other via contact of both electrodes with the bridge electrode BNE. As a result, even if the number of signal lines increases, and the degree of integration of a circuit increases, the first connection electrode CNE1 and the second connection electrode CNE2 which are physically disconnected from each other are electrically connected to each other, so that the display device DD of the invention may have high-resolution, high-speed driving, and high-robustness properties.

Although the invention has been described with reference to preferred embodiments of the invention, it will be understood by those skilled in the art that various modifications and changes in form and details may be made therein without departing from the spirit and scope of the invention as set forth in the following claims.

Accordingly, the technical scope of the invention is not intended to be limited to the contents set forth in the detailed description of the specification, but is intended to be defined by the appended claims.

What is claimed is:

1. A display device comprising:
a circuit layer; and
a light emitting element which is on the circuit layer and connected thereto,
wherein the circuit layer comprises:
a transistor;
an insulation layer on the transistor, the insulation layer comprising:
a side surface which defines a contact-hole of the insulation layer at which a portion of the transistor is exposed to outside the insulation layer, and
an upper surface from which the side surface extends;
a bridge electrode which extends along the side surface of the insulation layer and contacts the portion of the transistor which is exposed to outside the insulation layer; and
a connection electrode which connects to the transistor, the connection electrode comprising a first connection electrode which is directly on the bridge electrode and spaced apart from the portion of the transistor which is exposed to outside the insulation layer.

2. The display device of claim 1, wherein the transistor comprises a semiconductor layer which defines the portion of the transistor which is exposed to outside the insulation layer.

3. The display device of claim 2, wherein
the semiconductor layer includes an upper surface at which the semiconductor layer is exposed to outside the insulation layer, and
the connection electrode further comprises a second connection electrode on the upper surface of the semiconductor layer.

4. The display device of claim 3, wherein
the second connection electrode is spaced apart from the first connection electrode, along the bridge electrode; and
the second connection electrode is electrically connected to the first connection electrode via the bridge electrode.

5. The display device of claim 4, wherein a width of the contact-hole is about 0.5 micrometer to about 2 micrometers.

6. The display device of claim 4, wherein a depth of the contact-hole is about 1 micrometer to about 1.5 micrometer.

7. The display device of claim 3, wherein the bridge electrode comprises a material different from a material of each of the first connection electrode and of the second connection electrode.

8. The display device of claim 1, wherein
the bridge electrode has a length along the side surface of the insulation layer; and
the length of the bridge electrode is smaller than a depth of the contact-hole.

9. The display device of claim 1, wherein
the bridge electrode has an upper surface which is closest to the upper surface of the insulation layer;
a portion of the side surface which is between the upper surface of the insulation layer and the upper surface of the bridge electrode is exposed to outside the bridge electrode; and
the first connection electrode directly contacts the upper surface of the bridge electrode and the portion of the side surface which is exposed to outside the bridge electrode.

10. The display device of claim 1, wherein
the insulation layer further comprises:
a first insulation layer on the transistor; and
a second insulation layer on the first insulation layer, and the contact-hole passes through the first insulation layer and the second insulation layer.

11. The display device of claim 10, wherein the contact-hole comprises:
a first hole portion defined by a side surface of the first insulation layer;
a second hole portion defined by a side surface of the second insulation layer; and
a size of the first hole portion being smaller than a size of the second hole portion.

12. The display device of claim 1, wherein
the first connection electrode comprises portions which extend from the upper surface of the insulation layer and along the side surface thereof, the portions being spaced apart from each other to define an upper hole in the first connection electrode, and
a size of the upper hole increases in a direction from the upper surface of the insulation layer to the portion of the transistor which is exposed to outside the insulation layer.

13. The display device of claim 1, wherein the bridge electrode comprises an n-type dopant.

14. The display device of claim 1, wherein the circuit layer further comprises an organic layer which is on the insulation layer and comprises a side surface defining an upper contact-hole of the organic layer at which a portion of the first connection electrode is exposed to outside the organic layer.

15. The display device of claim 14, wherein the circuit layer further comprises:
an upper bridge electrode which extends along the side surface of the organic layer and contacts the portion of the first connection electrode which is exposed to outside the organic layer; and
an upper connection electrode which electrically connects the light emitting element to the connection electrode, the upper connection electrode being directly on the upper bridge electrode and spaced apart from the portion of the first connection electrode which is exposed to outside the organic layer.

16. A method for providing a display device, the method comprising:
providing a semiconductor pattern of a transistor, and an insulation layer which is on the transistor;
providing a contact-hole in the insulation layer which exposes a portion of the semiconductor pattern to outside the insulation layer, the insulation layer having a side surface which defines the contact-hole and an upper surface extended from the side surface;
providing a bridge electrode along the side surface of the insulation layer to contact the portion of the semiconductor pattern which is exposed to outside the insulation layer; and
providing a first connection electrode which connects a light emitting element to the transistor, the first connection electrode extended along the bridge electrode,
wherein the first connection electrode is electrically connected to the portion of the semiconductor pattern via the bridge electrode.

17. The method of claim 16, further comprising providing a second connection electrode contacting the portion of the semiconductor pattern and spaced apart from the first connection electrode along the bridge electrode.

18. The method of claim 17, wherein the first connection electrode and the second connection electrode are respective portions of a same material layer.

19. The method of claim 16, wherein the providing of the bridge electrode comprises:
providing a preliminary bridge electrode on the upper surface of the insulation layer, along the side surface of the insulation layer and along the portion of the semiconductor pattern; and
etching portions of the preliminary bridge electrode which are on the upper surface of the insulation layer and on the portion of the semiconductor pattern.

20. The method of claim 19, wherein the preliminary bridge electrode is provided by chemical vapor deposition.
